(19) United States
(12) Patent Application Publication
(10) Pub. No.: US 2026/0162727 A1
(43) Pub. Date: Jun. 11, 2026

(54) MEMORY DEVICE AND PROGRAM OPERATION THEREOF

(71) Applicant: Yangtze Memory Technologies Co., Ltd., Wuhan (CN)

(72) Inventors: Yang Zhang, Wuhan (CN); Bo Li, Wuhan (CN); Chao Wang, Wuhan (CN); Masao Kuriyama, Wuhan (CN)

(21) Appl. No.: 19/011,443

(22) Filed: Jan. 6, 2025

(30) Foreign Application Priority Data
Dec. 9, 2024 (CN) 202411808185.9

(51) Int. Cl. G11C 16/10; G11C 16/04; G11C 16/08; G11C 16/34

(52) U.S. Cl. CPC G11C 16/10; G11C 16/0483; G11C 16/08; G11C 16/3459

(57) ABSTRACT

In certain aspects, a memory device includes an array of memory cells, word lines respectively coupled to rows of the array of memory cells, and a peripheral circuit coupled to the array of memory cells through the word lines. The peripheral circuit is configured to, in a first loop of a program operation, apply a post-pulse voltage on a select word line of the word lines after applying a verify voltage on the select word line, ramp down a voltage on the select word line from the post-pulse voltage to a first supply voltage (Vdd), and immediately ramp up the voltage on the select word line from the first supply voltage to a first bias voltage.

### CROSS-REFERENCE TO RELATED APPLICATIONS

This application claims the benefit of priority to Chinese Application No. 202411808185.9, filed on Dec. 9, 2024, which is hereby incorporated by reference in its entirety.

### BACKGROUND

The present disclosure relates to memory devices and operation methods thereof.

Flash memory is a low-cost, high-density, non-volatile solid-state storage medium that can be electrically erased and reprogrammed. Flash memory includes NOR Flash memory and NAND Flash memory. Various operations can be performed by Flash memory, such as read, program (write), and erase. For NAND Flash memory, an erase operation can be performed at the block level, and a program operation or a read operation can be performed at the page level.

### SUMMARY

In one aspect, a memory device includes an array of memory cells, word lines respectively coupled to rows of the array of memory cells, and a peripheral circuit coupled to the array of memory cells through the word lines. The peripheral circuit is configured to, in a first loop of a program operation, apply a post-pulse voltage on a select word line of the word lines after applying a verify voltage on the select word line, ramp down a voltage on the select word line from the post-pulse voltage to a first supply voltage (Vdd), and immediately ramp up the voltage on the select word line from the first supply voltage to a first bias voltage.

In some implementations, to immediately ramp up the voltage on the select word line, the peripheral circuit is configured to ramp up the voltage on the select word line as soon as the voltage on the select word line reaches the first supply voltage.

In some implementations, the peripheral circuit is further configured to, in a second loop of the program operation immediately after the first loop, apply a program voltage to the select word line after the first bias voltage.

In some implementations, the peripheral circuit is further configured to, in the first loop of the program operation, ramp down a voltage on an unselect word line of the word lines from a pass voltage to the first supply voltage, and immediately ramp up the voltage on the unselect word line from the first supply voltage to a second bias voltage not greater than the first bias voltage.

In some implementations, the voltages on the select word line and the unselect word line are ramped down from a same first time and ramped up from a same second time.

In some implementations, the unselect word line includes a first unselect word line, a second unselect word line, and a third unselect word line. The first unselect word line is closer to the select word line than the second unselect word line, and the second unselect word line being closer to the select word line than the third unselect word. The second bias voltage on the first unselect word line is the same as the first bias voltage on the select word line. The second bias voltage on the second unselect word line is smaller than the first bias voltage. A third bias voltage on the third unselect word line is smaller than the second bias voltage on the second unselect word line.

In some implementations, the memory device further includes a source line coupled to the array of memory cells, drain select gate (DSG) transistors respectively coupled to columns of the array of memory cells, and a DSG line coupled to the DSG transistors. The peripheral circuit is coupled to the array of memory cells through the source line and the DSG line and is configured to in the first loop of the program operation, ramp down a voltage on the DSG line from a select voltage to a second supply voltage (Vss) smaller than the first supply voltage, and ramp up a voltage on the source line to a fourth bias voltage.

In some implementations, the voltages on the select word line and the DSG line are ramped down from a same first time until a same second time.

In some implementations, the memory device further includes a bit line coupled to the array of memory cells, source select gate (SSG) transistors respectively coupled to columns of the array of memory cells, and an SSG line coupled to the SSG transistors. The peripheral circuit is coupled to the array of memory cells through the bit line and the SSG line and is configured to, in the first loop of the program operation, ramp down a voltage on the SSG line from a select voltage to a second supply voltage (Vss) smaller than the first supply voltage, and ramp up a voltage on the bit line to a fourth bias voltage.

In some implementations, the voltages on the select word line and the SSG line are ramped down from a same first time until a same second time.

In some implementations, the peripheral circuit is further configured to, in a third loop of the program operation, ramp down the voltage on the select word line from the post-pulse voltage to the first supply voltage, and maintain the voltage on the select word line at the first supply voltage.

In another aspect, a method for operating a memory device is provided. The memory device includes an array of memory cells and word lines respectively coupled to rows of the array of memory cells. In a first loop of a program operation, a post-pulse voltage is applied on a select word line of the word lines after applying a verify voltage on the select word line. A voltage on the select word line is ramped down from the post-pulse voltage to a first supply voltage (Vdd). The voltage on the select word line is immediately ramped up from the first supply voltage to a first bias voltage.

In some implementations, to immediately ramp up the voltage on the select word line, the voltage on the select word line is ramped up as soon as the voltage on the select word line reaches the first supply voltage.

In some implementations, in a second loop of the program operation immediately after the first loop, a program voltage is applied to the select word line after the first bias voltage.

In some implementations, in the first loop of the program operation, a voltage on an unselect word line of the word lines is ramped down from a pass voltage to the first supply voltage The voltage on the unselect word line is immediately ramped up from the first supply voltage to a second bias voltage not greater than the first bias voltage.

In some implementations, the voltages on the select word line and the unselect word line are ramped down from a same first time and ramped up from a same second time.

In some implementations, the unselect word line includes a first unselect word line, a second unselect word line, and a third unselect word line. The first unselect word line is closer to the select word line than the second unselect word line, and the second unselect word line is closer to the select word line than the third unselect word line. The second bias voltage on the first unselect word line is the same as the first bias voltage on the select word line. The second bias voltage on the second unselect word line is smaller than the first bias voltage. A third bias voltage on the third unselect word line is smaller than the second bias voltage on the second unselect word line.

In some implementations, the memory device further includes a source line coupled to the array of memory cells, DSG transistors respectively coupled to columns of the array of memory cells, and a DSG line coupled to the DSG transistors. In the first loop of the program operation, a voltage on the DSG line is ramped down from a select voltage to a second supply voltage (Vss) smaller than the first supply voltage, and a voltage on the source line is ramped up to a fourth bias voltage.

In some implementations, the voltages on the select word line and the DSG line are ramped down from a same first time until a same second time.

In some implementations, the memory device further includes a bit line coupled to the array of memory cells, SSG transistors respectively coupled to columns of the array of memory cells, and an SSG line coupled to the SSG transistors. In the first loop of the program operation, a voltage on the SSG line is ramped down from a select voltage to a second supply voltage (Vss) smaller than the first supply voltage, and a voltage on the bit line is ramped up to a fourth bias voltage.

In some implementations, the voltages on the select word line and the SSG line are ramped down from a same first time until a same second time.

In some implementations, in a third loop of the program operation, the voltage on the select word line is ramped down from the post-pulse voltage to the first supply voltage. The voltage on the select word line is maintained at the first supply voltage.

In still another aspect, a system includes a memory device configured to store data, and a memory controller coupled to the memory device and configured to control the memory device. The memory device includes an array of memory cells, word lines respectively coupled to rows of the array of memory cells, and a peripheral circuit coupled to the array of memory cells through the word lines. The peripheral circuit is configured to, in a first loop of a program operation, apply a post-pulse voltage on a select word line of the word lines after applying a verify voltage on the select word line, ramp down a voltage on the select word line from the post-pulse voltage to a first supply voltage (Vdd), and immediately ramp up the voltage on the select word line from the first supply voltage to a first bias voltage.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a memory device including peripheral circuits, according to some aspects of the present disclosure.

FIG. 2 illustrates a side view of a cross-section of a memory cell array including a NAND memory string, according to some aspects of the present disclosure.

FIG. 3 illustrates a block diagram of a memory device including a memory cell array and peripheral circuits, according to some aspects of the present disclosure.

FIGS. 4A and 4B illustrate a waveform of word line voltages applied to a select word line in a program operation, according to some aspects of the present disclosure.

FIG. 5 illustrates timing diagrams of a program operation having multiple loops.

FIG. 6 illustrates timing diagrams of another program operation having multiple loops.

FIG. 7 illustrates timing diagrams of a program operation having multiple loops, according to some aspects of the present disclosure.

FIG. 8 illustrates timing diagrams of another program operation having multiple loops, according to some aspects of the present disclosure.

FIG. 9 illustrates timing diagrams and channel potential of still another program operation having multiple loops, according to some aspects of the present disclosure.

FIG. 10 illustrates timing diagrams of yet another program operation having multiple loops, according to some aspects of the present disclosure.

FIG. 11 illustrates a flowchart of a method for programming a memory device, according to some aspects of the present disclosure.

FIG. 12 illustrates a flowchart of another method for programming a memory device, according to some aspects of the present disclosure.

FIG. 13 illustrates a block diagram of a system having a memory device, according to some aspects of the present disclosure.

FIG. 14A illustrates a diagram of a memory card having a memory device, according to some aspects of the present disclosure.

FIG. 14B illustrates a diagram of a solid-state drive (SSD) having a memory device, according to some aspects of the present disclosure.

The present disclosure will be described with reference to the accompanying drawings.

### DETAILED DESCRIPTION

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Memory devices, such as NAND Flash memory devices, can store more than a single bit of information into each memory cell with multiple states in order to increase the storage capacity and reduce the cost per bit. The program operation of a NAND Flash memory device involves a number of program cycles and verify cycles. At the end of each verify cycle, all the word lines are recovered to the drain supply voltage Vdd, and the drain select gate (DSG) and source select gate (SSG) lines are recovered to the source supply voltage Vss, which can down-couple the channel potential, in particular, at the select NAND memory string programmed memory cell region close to the select word line. The down-coupled channel potential, however, can cause program disturbance in the subsequent program cycle due to the hot carrier injection (HCI) effect. To mitigate these issues, bias voltage(s) can be applied to the word lines close to the select word line at the beginning of the affected program cycle to clean the accumulated electrons in the channel in a so-called “pre-pulse period” in the program cycle. The additional pre-pulse period, however, prolongs the duration of the program cycle, thereby becoming the bottleneck of saving program time (t_{PROG}).

On the other hand, at the end of a verify cycle, failure bit count (FBC) needs to be performed in a reserved time period when all the word lines are recovered to Vdd. Some efforts have been made to merge the pre-pulse period in a program cycle and the FBC period in the preceding verify cycle in order to reduce the total program time as well as the power consumption from the ramping up/down of the word line voltages. However, due to the different voltage driving capabilities between unselect word lines with different bias voltages (e.g., Vss and a positive bias voltage), the HCI effect can still occur between those unselect word lines due to voltage stress.

To address one or more of the aforementioned issues, the present disclosure provides an improved recovery/pre-pulse scheme that avoids voltage stress between different adjacent unselect word lines, thereby reducing the HCI effect. After applying the verify voltage, all the word lines can be ramped down to the same supply voltage (e.g., Vdd) and then immediately ramped up to from the same supply voltage to their respective bias voltages for channel cleaning. Since all the word lines are recovered to the same supply voltage with the same voltage driving capability, the voltage stress between the adjacent unselect word lines can be greatly reduced. Charge sharing between far-end and near-end word lines can speed up the far-end word lines to reach their target voltages as well. The voltages on the word lines can start to ramp up as soon as reaching the supply voltage without significantly affecting the program time. In some implementations, the voltages on the DSG line and/or SSG line are ramped down to another supply voltage (e.g., Vss) at the same time as the word lines to avoid the threshold voltage shift due to the HCI effect under certain program patterns. The recovery/pre-pulse scheme is a “by-loop” recovery/pre-pulse scheme that can be enabled and disabled in different loops of a program operation to balance the performance and program time.

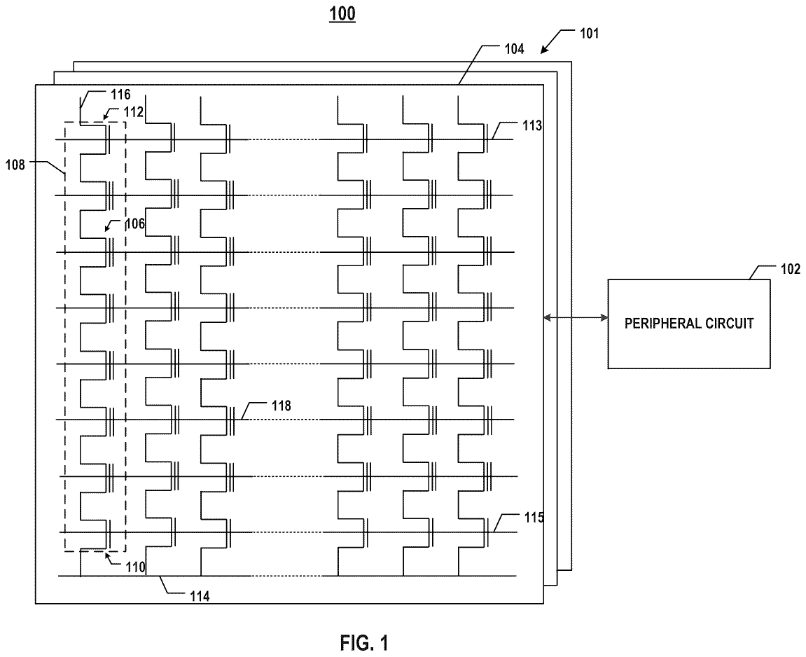

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge, which depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is an SLC that has two possible levels (memory states) and thus, can store one bit of data. For example, the first level “0” can correspond to a first range of threshold voltages, and the second level “1” can correspond to a second range of threshold voltages. In some implementations, each memory cell 106 is an xLC that is capable of storing more than a single bit of data in more than four levels. For example, the xLC may store two bits per cell (MLC), three bits per cell (TLC), or four bits per cell (QLC)). Each xLC can be programmed to assume a range of possible nominal storage values (i.e., corresponding to 2^{N} pieces of N-bits data). In some implementations, at least one of memory cells 106 is set to one of 2^{N} levels corresponding to a piece of N-bits data, where N is an integer greater than 1.

As shown in FIG. 1, each NAND memory string 108 can also include a source select gate (SSG) transistor 110 (a.k.a., bottom select gate (BSG) transistor) at its source end and a drain select gate (DSG) transistor 112 (a.k.a., top select gate (TSG) transistor) at its drain end. SSG transistor 110 and DSG transistor 112 can be configured to activate select NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. The drain of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., a positive voltage greater than the threshold voltage of DSG transistor 112) or a deselect voltage (e.g., the ground voltage) to the gate of respective DSG transistor 112 through one or more DSG lines 113 and/or by applying a select voltage (e.g., a positive voltage greater than the threshold voltage of SSG transistor 110) or a deselect voltage (e.g., the ground voltage) to the gate of respective SSG transistor 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a select block 104, source lines 114 coupled to select block 104 as well as unselect blocks 104 in the same plane as select block 104 can be biased with an erase voltage (Vers), such as a high positive bias voltage (e.g., 20 V or more). Memory cells 106 of adjacent NAND memory strings 108 can be coupled through word lines 118 that select which row of memory cells 106 is affected by read and program operations. In some implementations, each word line 118 is coupled to a plurality of memory cells 106. Each word line 118 can include a plurality of control gates (gate electrodes) at each memory cell 106 and a gate line coupling the control gates.

As shown in FIG. 1, memory cell array 101 can include an array of memory cells 106 in a plurality of rows and a plurality of columns in each block 104. One column of memory cells corresponds to one NAND memory string 108, according to some implementations. The plurality of rows of memory cells 106 can be respectively coupled to word lines 118, and the plurality of columns of memory cells 106 can be respectively coupled to bit lines 116. Peripheral circuit 102 can be coupled to memory cell array 101 through bit lines 116 and word lines 118.

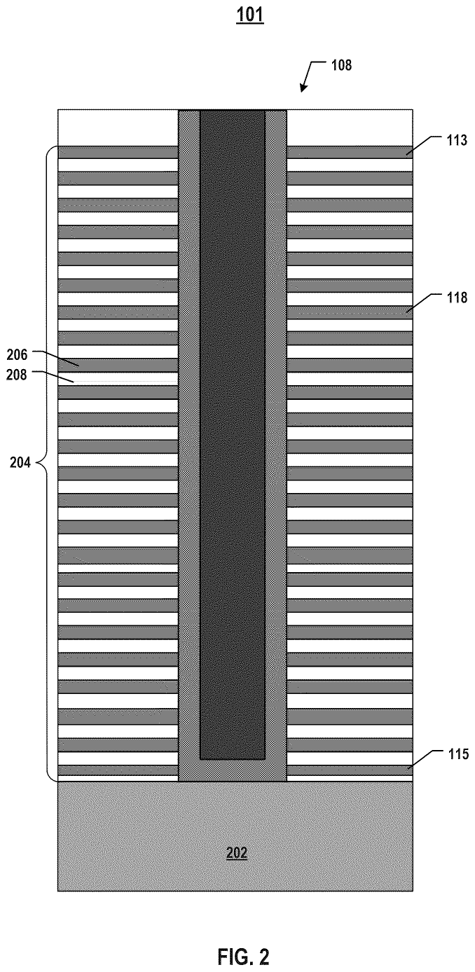

FIG. 2 illustrates a side view of a cross-section of memory cell array 101 including NAND memory string 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding memory cells 106, the gates of DSG transistors 112, or the gates of SSG transistors 110, and can extend laterally as DSG line 113 at the top of memory stack 204, SSG line 115 at the bottom of memory stack 204, or word line 118 between DSG line 113 and SSG line 115

As shown in FIG. 2, NAND memory string 108 includes a channel structure extending vertically through memory stack 204. In some implementations, the channel structure includes a channel hole filled with semiconductor material(s) (e.g., as a semiconductor channel) and dielectric material(s) (e.g., as a memory film). It is understood that although not shown in FIG. 2, additional components of memory cell array 101 can be formed including, but not limited to, gate line slits/source contacts, local contacts, interconnect layers, etc.

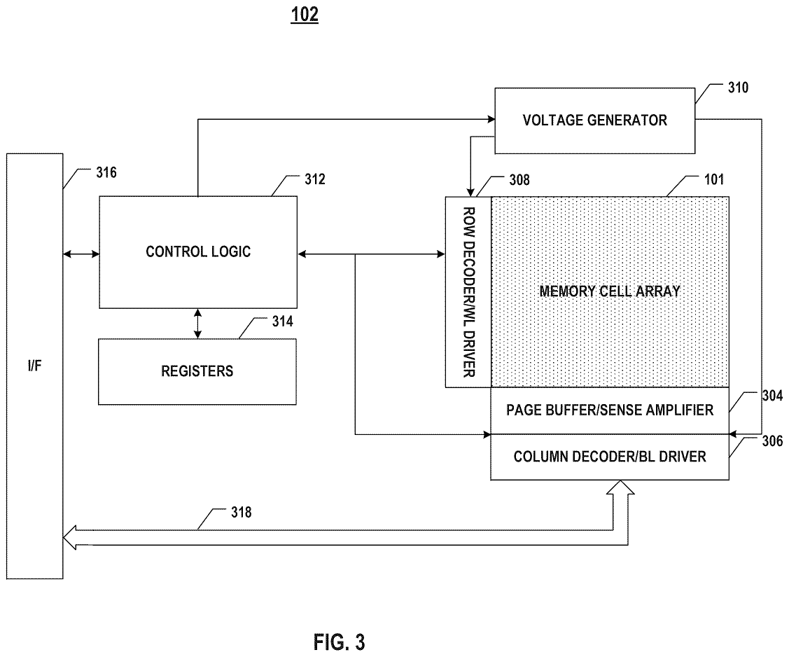

Referring back to FIG. 1, peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each select memory cell 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits including a page buffer/sense amplifier 304, a column decoder/bit line driver 306, a row decoder/word line driver 308, a voltage generator 310, control logic 312, registers 314, an interface (I/F) 316, and a data bus 318. It is understood that in some examples, additional peripheral circuits not shown in FIG. 3 may be included as well.

Page buffer/sense amplifier 304 can be configured to sense (read) and program (write) data from and to memory cell array 101 according to the control signals from control logic 312. In one example, page buffer/sense amplifier 304 may store one or more pages of program data (write data, referred to herein as “data page”) to be programmed. In another example, page buffer/sense amplifier 304 may verify programmed select memory cells 106 in each program/verify cycle in a program operation to ensure that the data has been properly programmed into memory cells 106 coupled to select word lines 118. In still another example, page buffer/sense amplifier 304 may also sense the low power signals from bit line 116 that represents a data bit stored in memory cell 106 and amplify the small voltage swing to recognizable logic levels in a read operation.

Column decoder/bit line driver 306 can be configured to be controlled by control logic 312 and select one or more NAND memory strings 108 by applying bit line voltages generated from voltage generator 310. Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Voltage generator 310 can be configured to be controlled by control logic 312 and generate the word line voltages (e.g., read voltage, program voltage, channel pass voltage, local voltage, verify voltage, etc.), bit line voltages, and source line voltages to be supplied to memory cell array 101.

Control logic 312 can be coupled to each peripheral circuit described above and configured to control the operations of each peripheral circuit. Registers 314 can be coupled to control logic 312 and include status registers, command registers, and address registers for storing status information, command operation codes (OP codes), and command addresses for controlling the operations of each peripheral circuit. Interface 316 can be coupled to control logic 312 and act as a control buffer to buffer and relay control commands received from a memory controller (not shown) and/or a host (not shown) to control logic 312 and status information received from control logic 312 to the memory controller and/or the host. Interface 316 can also be coupled to column decoder/bit line driver 306 via data bus 318 and act as a data input/output (I/O) interface and a data buffer to buffer and relay the data to and from memory cell array 101.

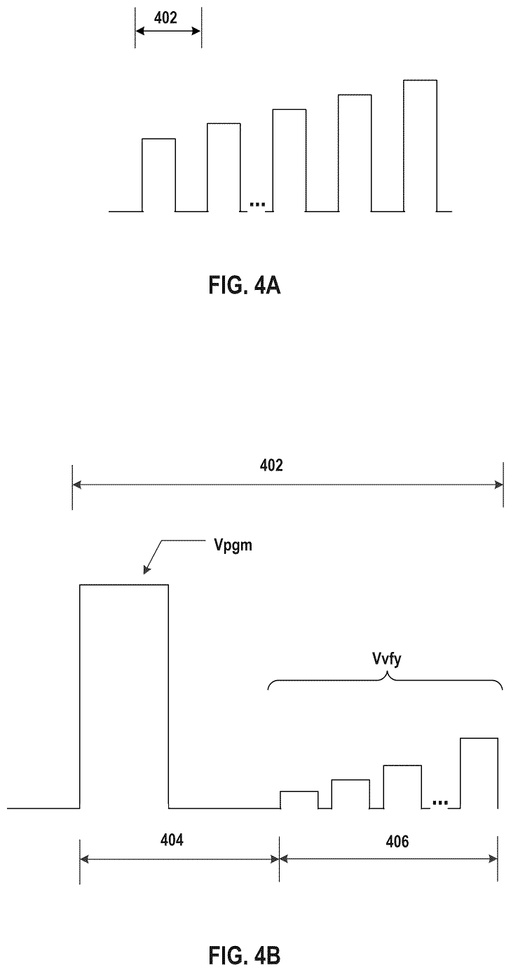

To perform a program operation, in addition to page buffer/sense amplifier 304 providing to each select memory cell 106 the corresponding piece of data, row decoder/word line driver 308 can be configured to apply program voltages and verify voltages to a select word line 118 coupled to a select row of memory cells 106 in one or more program/verify cycles in order to raise the threshold voltage of each select memory cell 106 to a desired level (into a desired range of threshold voltages) based on the corresponding piece of data. For example, FIGS. 4A and 4B illustrate a waveform of word line voltages applied to a select word line in a program operation, according to some aspects of the present disclosure.

As shown in FIGS. 4A and 4B, the program operation includes one or more loops 402, each of which includes a program cycle 404 and a verify cycle 406, according to some implementations. As shown in FIG. 4B, in each loop 402, row decoder/word line driver 308 can be configured to apply a program voltage (Vpgm) on select word line 118 to select row of memory cells 106 in program cycle 404 and sequentially apply one or more verify voltages (Vvfy) with incremental changes of voltage levels to verify select row of memory cells 106 in verify cycle 406. That is, in each loop 402, peripheral circuit 102 can perform verification of select row of memory cells 106 at one or more levels in verify cycle 406 after applying a program voltage in program cycle 404. The number of verify voltages applied in verify cycle 406 depends on the level being programmed by the specific loop 402, according to some implementations. As a result, at the end of the program operation, for example, select memory cell 106 may be programmed into one of the 2^{N} levels based on the corresponding N bits of data to be stored in select memory cell 106, where N is a positive integer. In some implementations, the program operation is an incremental step pulse program (ISPP), which gradually increases the program voltage on a step-voltage basis in different loops 402. The magnitude of this “step” (e.g., the increase in magnitude of the program voltage in each loop 402 relative to the program voltage in the immediately previous loop 402) is known as the “pulse step height.”

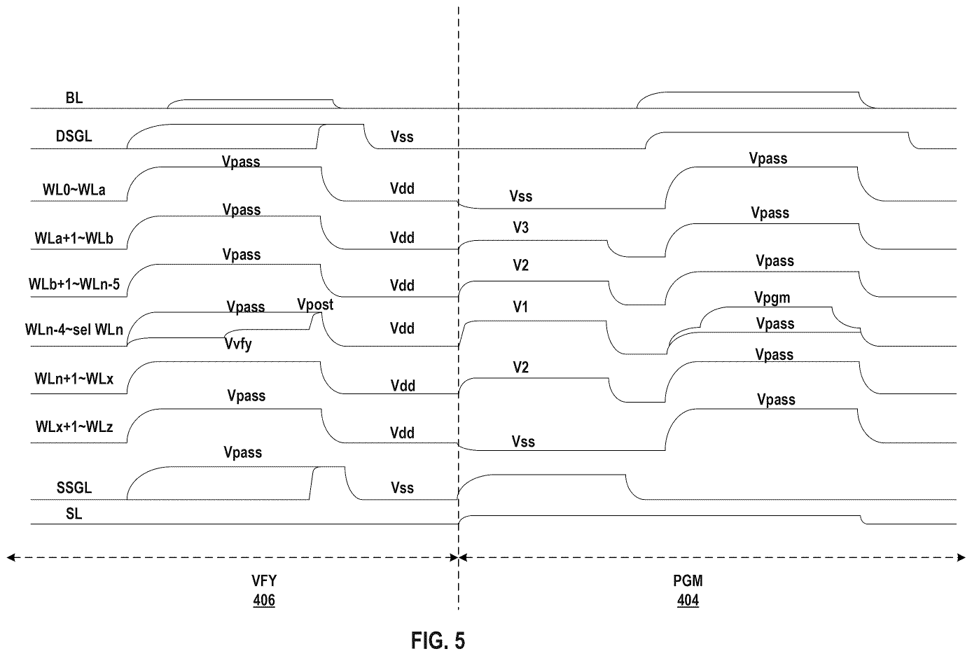

FIG. 5 illustrates timing diagrams of a program operation having multiple loops. The program operation includes a plurality of loops (e.g., N loops). Each loop of the program operation includes a program cycle and a verify cycle, as described above in FIGS. 4A and 4B. FIG. 5 shows verify cycle 406 (VFY) in a loop and program cycle 404 (PGM) in another loop immediately after verify cycle 406 in the previous loop. Verify cycle 406 includes a verify period (phase) in which a verify voltage (Vvfy) having one or more verify voltage pulses is applied on the select word line (sel WLn) to verify select memory cells coupled to the select word line at one or more levels. In the verify period, a pass voltage (Vpass) is applied on each unselect word line. At the end of the verify period, a post-pulse voltage (Vpost) is applied on the select word line. Verify cycle 406 also includes a post-pulse period (phase, a.k.a. recovery period) after the verify period. In the post-pulse period, the voltage on each unselect word line is ramped down from the pass voltage to a first supply voltage (Vdd), and the voltage on the select word line is ramped down from the post-pulse voltage to the first supply voltage. In the post-pulse period, the voltage on each of the DSG line (DSGL) and SSG line (SSGL) is ramped down to a second supply voltage (Vss), such as the ground voltage (0V).

As shown in FIG. 5, program cycle 404 includes a pre-pulse period (phase) after the post-pulse period of verify cycle 406. In the pre-pulse period, the voltage on each of the unselect word line and select word line is ramped up or down from the first supply voltage to the respective bias voltage. For example, the voltage on each of the select word line and a first group of unselect word lines (WLn-4-sel WLn) is ramped up to a first bias voltage (V1), the voltage on each of a second group of unselect word lines (WLb+1-WLn-5, and WLn+1-WLx) is ramped up to a second bias voltage (V2), the voltage on each of a third group of unselect word lines (WLa+1-WLb) is ramped up to a third bias voltage (V3), and the voltage on each of a fourth group of unselect word lines (WL0-WLa, and WLx+1-WLz) is ramped down to a second supply voltage (Vss). Program cycle 404 further includes a program period (phase) after the pre-pulse period in which a program voltage (Vpgm) having one or more program voltage pulses is applied to the select word line to program the select memory cells to one or more levels. In the program period, the pass voltage is applied to each unselect word line.

In the post-pulse period of verify cycle 406, the programmed memory cells close to the select word line (e.g., memory cells coupled to the unselect word lines WLn-4-WLn-1 in FIG. 5) are turned off early due to their relatively high threshold voltages, thereby down-coupling the channel potential in this region from 0V to a negative voltage (e.g., −3V). Since the channel potential in the region of the erase memory cells (e.g., memory cells coupled to the unselect word lines WLn+1-WLz in FIG. 5) is at a positive voltage, the HCI effect can occur due to the large channel potential difference and cause program disturbance. In the pre-charge period of program cycle 404 immediately after verify cycle 406, biasing each word line at the respective bias voltage as shown in FIG. 5 forms a channel potential distribution that can remove electrons accumulated in the select word line region of the channel, thereby mitigating the HCI effect and the possible program disturbance before the program period. However, the introduction of the post-pulse period in verify cycle 406 and the pre-pulse period in program cycle 404 causes a significant overhead to the total program time.

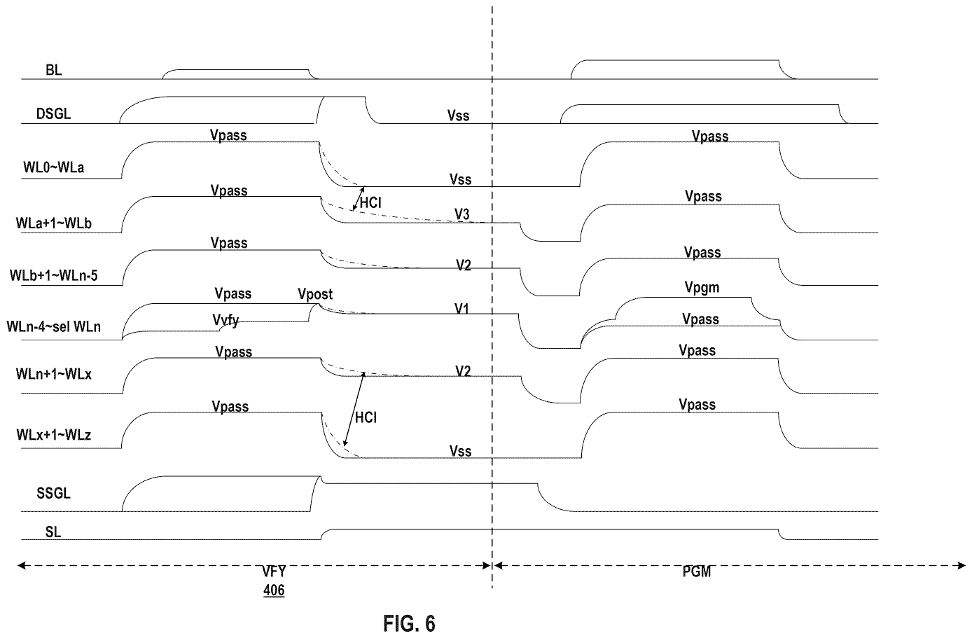

Since part of the post-pulse period in verify cycle 406 is reserved only for logic operation of FBC without voltage operation on the word lines, the post-pulse period in verify cycle 406 and the pre-pulse period in program cycle 404 may be “merged” to reduce the time overhead. FIG. 6 illustrates timing diagrams of another program operation having multiple loops. As shown in FIG. 6, after the verify period of verify cycle 406, instead of ramping down the voltage on each word line to the first supply voltage (Vdd) as shown in FIG. 5, the voltage on each word line is ramped down to the respective bias voltage directly. For example, the voltage on each of the select word line and the first group of unselect word lines (WLn-4-sel WLn) is ramped down from the post-pulse voltage (Vpost) or pass voltage (Vpass) to the first bias voltage (V1) directly using a first bias voltage regulator, the voltage on each of the second group of unselect word lines (WLb+1-WLn-5, and WLn+1-WLx) is ramped down from the pass voltage to the second bias voltage (V2) directly using a second bias voltage regulator, the voltage on each of the third group of unselect word lines (WLa+1-WLb) is ramped down from the pass voltage to the third bias voltage (V3) directly using a third bias voltage regulator, and the voltage on each of the fourth group of unselect word lines (WL0-WLa, and WLx+1-WLz) is ramped down from the pass voltage to the second supply voltage (Vss) directly using a second supply voltage source.

It is understood that the solid lines in FIG. 6 show the ideal timing diagram of the voltage signals on the word lines. In practice, however, due to the limited voltage driving capabilities, the dash-dotted lines in FIG. 6 show the actual timing diagram of the voltage signals on the word lines. Moreover, since the supply voltage source has a higher voltage driving capability than the bias voltage regulator (e.g., driving faster), as shown in FIG. 6, voltage stress occurs between the fourth group of unselect word lines (WL0-WLa) and the adjacent third group of unselect word lines (WLa+1-WLb), i.e., between WLa+1 and WLa, as well as between the fourth group of unselect word lines (WLx+1-WLz) and the adjacent second group of unselect word lines (WLn+1-WLx), i.e., between WLx+1 and WLx. Such voltage stress can be repeated every time the select word line is switched between different word lines. As a result, the HCI effect can still occur between WLa+1 and WLa and WLx+1 and WLx, as indicated in FIG. 6.

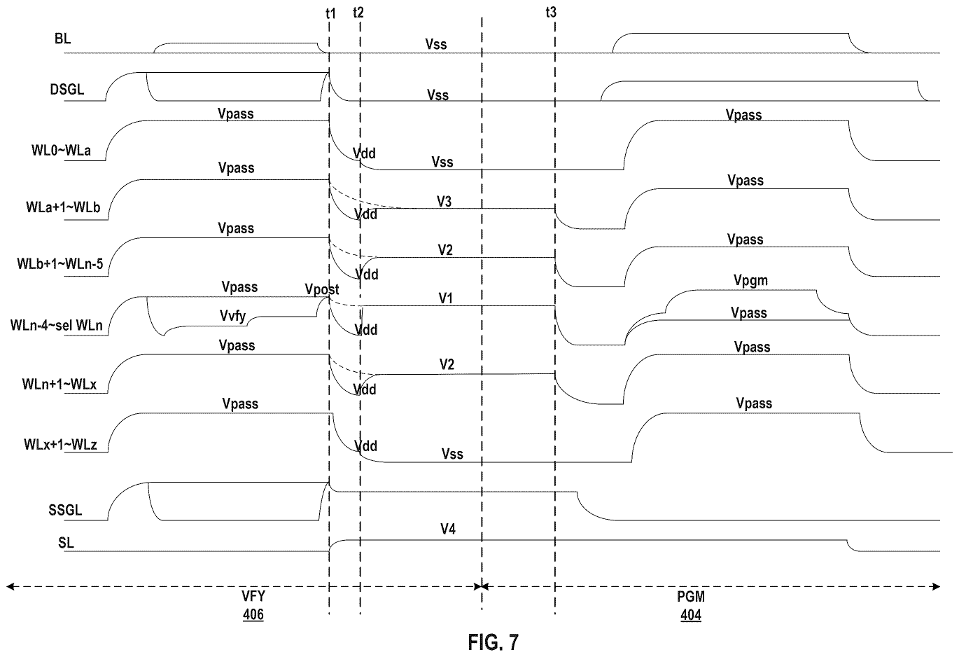

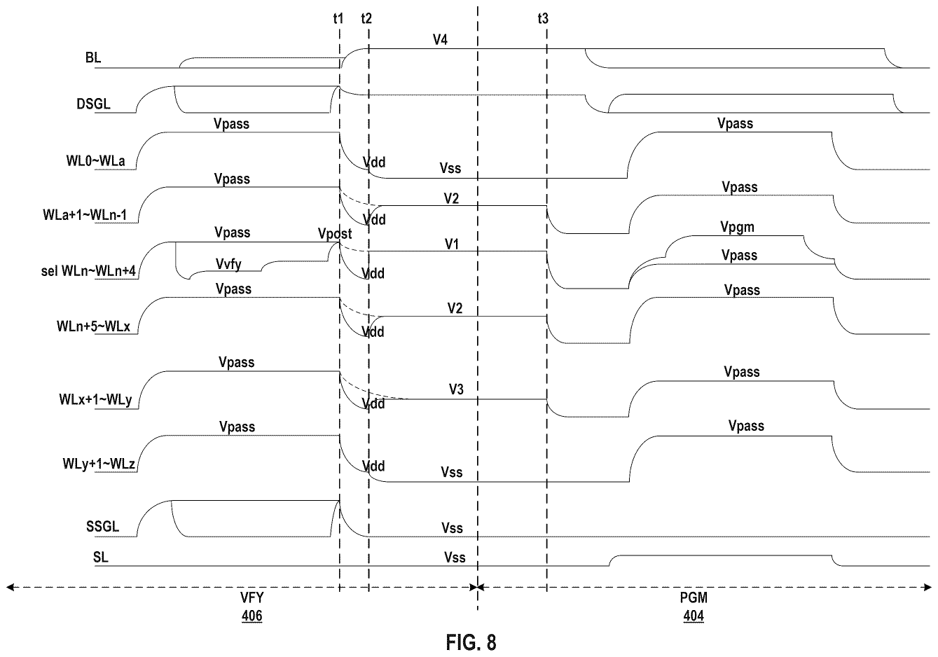

To mitigate the HC effect between adjacent word lines due to the different voltage driving capabilities, in the improved recovery/pre-pulse scheme disclosed herein, all the word lines can be recovered to the same supply voltage (e.g., Vdd) using the same supply voltage source before ramping up to their respective bias voltages. For example, FIGS. 7 and 8 illustrate timing diagrams of program operations having multiple loops, according to some aspects of the present disclosure. The program operation can include a plurality of loops (e.g., N loops). Each loop of the program operation can include a program cycle and a verify cycle, as described above in FIGS. 4A and 4B. FIGS. 7 and 8 show verify cycle 406 (VFY) in a first loop and program cycle 404 (PGM) in a second loop immediately after the first loop. It is understood that the “first loop” does not have to be the very first loop in the program operation as long as there is another loop, e.g., the “second loop,” immediately afterward.

In some implementations, verify cycle 406 includes a verify period (phase) in which word line driver 308 of peripheral circuit 102 is configured to apply a verify voltage (Vvfy) having one or more verify voltage pulses on a select word line (sel WLn) to verify select memory cells coupled to the select word line at one or more levels. At the end of the verify period, for example, at a first time t1 in FIGS. 7 and 8, word line driver 308 of peripheral circuit 102 is configured to apply a post-pulse voltage (Vpost) on the select word line, according to some implementations. For example, the voltage on the select word line may be ramped up from the verify voltage to the post-pulse voltage. In some implementations, in the verify period, word line driver 308 of peripheral circuit 102 is also configured to apply a pass voltage (Vpass) to each unselect word line. The pass voltage can be greater than the threshold voltages of the unselect memory cells, such that the channels of the selected NAND memory strings become conductive in the verify period. In some implementations, the pass voltage is greater than the verify voltage, such that at the end of the verify period, for example, at a first time t1 in FIGS. 7 and 8, the voltage on the select word line is up-coupled/boosted to the post-pulse voltage, which is the same as the pass voltage.

In some implementations, verify cycle 406 also includes a post-pulse period (phase, a.k.a. recovery period) after the verify period. In the post-pulse period, word line driver 308 of peripheral circuit 102 can be further configured to ramp down the voltage on the select word line from the post-pulse voltage to a first supply voltage (Vdd), starting from the first time t1, and then immediately ramp up the voltage on the select word line from the first supply voltage to a first bias voltage (V1) at a second time t2 after the first time t1. That is, the voltage on the select word line can be ramped down from the post-pulse voltage to the first supply voltage between the first time t1 and the second time t2, for example, using a first voltage source (e.g., a drain voltage source). For example, the time period between the first and second times t1 and t2 in which the voltage on the select word line is driven by the first voltage source may be less than 0.5 μs, such as about 0.2 μs. To immediately ramp up the voltage on the select word line at time t2, word line driver 308 of peripheral circuit 102 can be configured to ramp up the voltage on the select word line as soon as the voltage on the select word line reaches the first supply voltage.

Similarly, in the post-pulse period, word line driver 308 of peripheral circuit 102 can be further configured to ramp down the voltage on each unselect word line from the pass voltage to the same first supply voltage (Vdd), starting from the same first time t1, and then immediately ramp up the voltage on the unselect word line from the first supply voltage to a respective bias voltage (e.g., V1, V2, or V3) or a second supply voltage (Vss) that is not greater than the first bias voltage (V1) at the same second time t2. That is, the voltage on the unselect word line can be ramped down from the pass voltage to the first supply voltage between the first time t1 and the second time t2, for example, using the same first voltage source (e.g., a drain voltage source). For example, the time period between the first and second times t1 and t2 in which the voltage on the unselect word line is driven by the first voltage source may be less than 0.5 μs, such as about 0.2 μs. To immediately ramp up the voltage on the unselect word line at time t2, word line driver 308 of peripheral circuit 102 can be configured to ramp up the voltage on the unselect word line as soon as the voltage on the unselect word line reaches the first supply voltage. In some implementations, the voltages on the select word line and the unselect word lines are ramped down from the same first time t1 and ramped up from the same second time t2.

Since all the word lines (including the select word line and each unselect word line) can be driven by the same voltage source between the same first and second times t1 and t2 when they are ramped down to the same voltage, voltage stress between adjacent unselect word lines as described above with respect to FIG. 6 can be suppressed, thereby avoiding the resulting HCI effect. Moreover, it is understood that due to the resistance and capacitance of the memory cell array, word lines with different distances to word line driver 308 of peripheral circuit 102 can be driven at different rates. As shown in FIGS. 7 and 8, between the first and second times t1 and t2, the solid lines show the voltage change of the near-end word lines (that are closest to word line driver 308), while the dashed lines show the voltage change of the far-end word lines (that are farthest to word line driver 308). When the near-end word lines are ramped down to the first supply voltage (Vdd, e.g., about 2V), the far-end word lines are at a voltage that is higher than the first supply voltage (Vdd+ΔV, e.g., about 4V), which is sufficient to avoid the HCI effect at the second time t2. On the other hand, the charge sharing between the near-end word lines and the far-end word lines can also reduce the time to reach the bias voltages.

The unselect word lines can be categorized into different groups depending on their distances from the select word line and the program direction of the word lines, and different bias voltages (e.g., V1, V2, and V3) can be assigned to different groups of unselect word lines to form a bias voltage distribution to better clean the channels before the next program period. In some implementations, the first bias voltage is greater than the second bias voltage, which is greater than the third bias voltage, which is, in turn, greater than the second supply voltage (Vss), i.e., V1>V2>V3>Vss. For example, the first bias voltage may be about 4.5V, the second bias voltage may be about 3.5V, the third bias voltage may be about 2.5V, and the second supply voltage may be 0V. In other words, the closer to the select word line, the greater the bias voltage is assigned to the unselect word line group, according to some implementations.

In some implementations as shown in FIG. 7 in which the program direction is from the bit line (BL) to the source line (SL), e.g., from top to bottom, the voltage on each of the select word line and a first group of unselect word lines (WLn-4-sel WLn) is ramped up from the first supply voltage (Vdd) to the first bias voltage (V1) using a first bias voltage regulator, the voltage on each of a second group of unselect word lines (WLb+1-WLn-5, and WLn+1-WLx) is ramped up from the first supply voltage (Vdd) to the second bias voltage (V2) using a second bias voltage regulator, the voltage on each of a third group of unselect word lines (WLa+1-WLb) is ramped up from the first supply voltage (Vdd) to the third bias voltage (V3) using a third bias voltage regulator, and the voltage on each of a fourth group of unselect word lines (WL0-WLa, and WLx+1-WLz) is ramped down from the first supply voltage (Vdd) to the second supply voltage (Vss) using a second voltage source (e.g., a source voltage source). In some implementations as shown in FIG. 8 in which the program direction is from the source line (SL) to the bit line (BL), e.g., from bottom to top, the voltage on each of the select word line and a first group of unselect word lines (sel WLn-WLn+4) is ramped up from first supply voltage (Vdd) to the first bias voltage (V1) using a first bias voltage regulator, the voltage on each of a second group of unselect word lines (WLa+1-WLn-1, and WLn+5-WLx) is ramped up from first supply voltage (Vdd) to the second bias voltage (V2) using a second bias voltage regulator, the voltage on each of a third group of unselect word lines (WLx+1-WLy) is up down from first supply voltage (Vdd) to the third bias voltage (V3) using a third bias voltage regulator, and the voltage on each of a fourth group of unselect word lines (WL0-WLa, and WLy+1-WLz) is ramped down from first supply voltage (Vdd) to the second supply voltage (Vss) using the second voltage source (e.g., a source voltage source).

As shown in FIGS. 7 and 8, word line driver 308 of peripheral circuit 102 can be further configured to maintain the voltage on each of the select word line and unselect word line on the respective bias voltage (e.g., V1, V2, or V3) or second supply voltage (Vss) from the second time t2 in verify cycle 406 in the first loop to a third time t3 in program cycle 404 of the second loop immediately after the first loop. The time period between the second and third times t2 and t3 is the result of merging the post-pulse/recovery period of verify cycle 406 and the pre-pulse period of subsequent program cycle 404 as described above with respect to FIG. 6, and thus, may be viewed as a merged recovery/pre-pulse period of verify cycle 406 and subsequent program cycle. In other words, the bias voltages or the second supply voltage can be maintained on the word lines in the merged recovery/pre-pulse period of verify cycle 406 and subsequent program cycle.

As shown in FIGS. 7 and 8, program cycle 404 in the second loop can include, after the merged recovery/pre-pulse period, a program period (phase) in which word line driver 308 of peripheral circuit 102 can be further configured to apply a program voltage (Vpgm) having one or more program voltage pulses on the select word line to program the select memory cells to one or more levels. In the program period, word line driver 308 of peripheral circuit 102 can also be configured to apply the pass voltage (Vpass) on each unselect word line to make the channels conductive for programming.

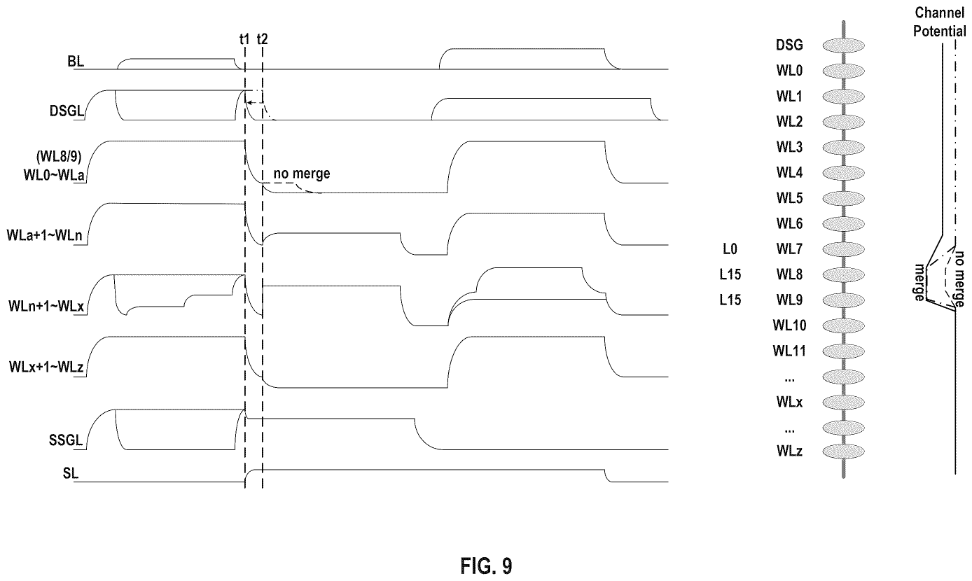

FIG. 9 illustrates timing diagrams and channel potential of still another program operation having multiple loops, according to some aspects of the present disclosure. Under certain program patterns (threshold voltage distribution), for example as shown in FIG. 9 when memory cells coupled to word line 7 (WL7) are programmed to the lower level (e.g., erased state L0) while memory cells coupled to adjacent word lines 8 and 9 (WL8 and WL9) are programmed to the highest level (e.g., L15 for QLCs), the merge of the post-pulse period and the pre-pulse period described in FIG. 6 can decrease the channel potential at the corresponding region, which causes a large channel potential drop (indicated by the dash-dotted line in the channel potential diagram). The resulting HCI effect can shit up the threshold voltages of the memory cells coupled to word line 7. One solution to mitigate this is to lower the channel potential of the programmed memory cells (indicated by the solid line in the channel potential diagram) by turning off the DSG transistor earlier, from the second time t2 to the first time t1. In other words, in the merged recovery/pre-pulse period, instead of ramping down the voltage on the DSG line after the voltages on the word lines have been ramped down as shown in FIG. 6, the voltage on the DSG line and/or the SSG line (depending on the program direction) can be ramped down at the same time as the voltages on the word lines in the merged recovery/pre-pulse period, as shown in FIGS. 7 and 8.

In some implementations, as shown in FIG. 7, in the merged recovery/pre-pulse period, word line driver 308 of peripheral circuit 102 is further configured to ramp down the voltage on the DSG line (DSGL) from a select voltage to the second supply voltage (Vss) smaller than the first supply voltage (Vdd) to turn off the DSG transistors coupled to the DSG line. The select voltage can be higher than the threshold voltage of the DSG transistors, such that the DSG transistors can be switched from on to off between the first and second times t1 and t2. The voltages on the select word line and the DSG line can be ramped down from the same first time t1 until the same second time t2 to lower the channel potential between the DSG line and the select word line, thereby mitigating the HCI effect as described above with respect to FIG. 9. In some implementations, in the merged recovery/pre-pulse period, word line driver 308 of peripheral circuit 102 is further configured to ramp up the voltage on the source line to a fourth bias voltage (V4) since the program direction in FIG. 7 is from the bit line to the source line.

In some implementations, as shown in FIG. 8, in the merged recovery/pre-pulse period, word line driver 308 of peripheral circuit 102 is further configured to ramp down the voltage on the SSG line (SSGL) from a select voltage to the second supply voltage (Vss) smaller than the first supply voltage (Vdd) to turn off the SSG transistors coupled to the SSG line. The select voltage can be higher than the threshold voltage of the SSG transistors, such that the SSG transistors can be switched from on to off between the first and second times t1 and t2. The voltages on the select word line and the SSG line can be ramped down from the same first time t1 until the same second time t2 to lower the channel potential between the SSG line and the select word line, thereby mitigating the HCI effect as described above with respect to FIG. 9. In some implementations, the merged recovery/pre-pulse period, word line driver 308 of peripheral circuit 102 is further configured to ramp up the voltage on the bit line to a fourth bias voltage (V4) since the program direction in FIG. 8 is from the source line to the bit line.

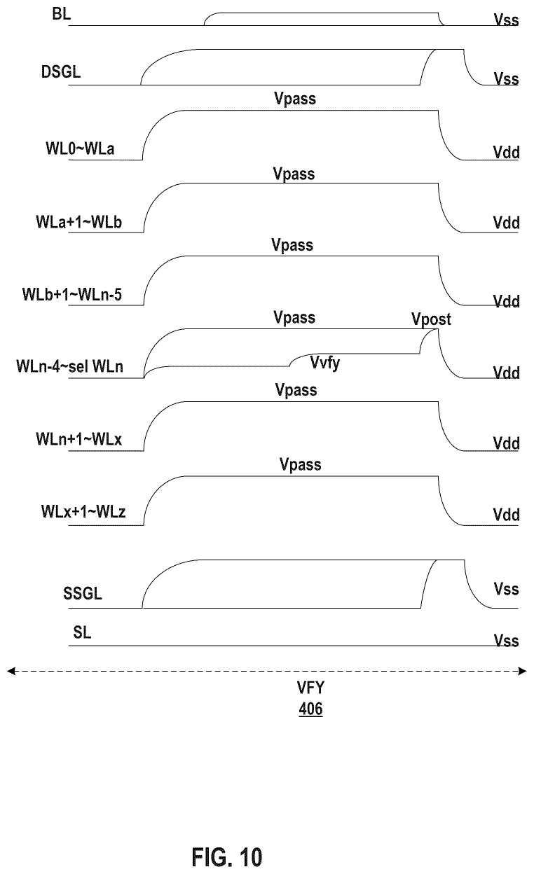

It is understood that in a multi loop program operation, the operations described above with respect to FIGS. 7-9 do not have to be performed in each loop. In other words, the recovery/pre-pulse scheme disclosed herein is a “by-loop” recovery/pre-pulse scheme that can be enabled and disabled in different loops of a program operation to balance the performance and program time. For example, FIG. 10 illustrates timing diagrams of yet another program operation having multiple loops, according to some aspects of the present disclosure. As shown in FIG. 10, in the post-pulse period of verify cycle 406 in a third loop that is different from the first and second loops described above in FIGS. 7 and 8, word line driver 308 of peripheral circuit 102 can be further configured to ramp down the voltage on the select word line from the post-pulse voltage (Vpost) to the first supply voltage (Vdd), and then maintain the voltage on the select word line at the first supply voltage. Similarly, word line driver 308 of peripheral circuit 102 can be further configured to ramp down the voltage on each unselect word line from the pass voltage (Vpass) to the first supply voltage, and then maintain the voltage on the select word line at the first supply voltage. In some implementations, the third loop described in FIG. 10 is the last loop of the program operation, and the program operation ends after verify cycle 406. In some implementations, the third loop described in FIG. 10 is one of the first several loops of the program operation, and the program operation continues with program cycle 404 (e.g., as shown in FIG. 5) after verify cycle 406. That is, the operations described with respect to FIG. 10 can be applied to the first several loops and/or the last loop of a program operation, while the operations described with respect to FIGS. 7-9 can be applied to the remaining loops of the program operation. Moreover, different from FIGS. 7-9 in which the voltage on the DSG line/SSG line is ramped down from the select voltage to the second supply voltage at the same time as the voltage on the word line ramping down to the first supply voltage, as shown in FIG. 10, the voltage on the DSG line (DSGL)/SSG line (SSGL) is ramped down from the select voltage to the second supply voltage (Vss) after ramping down the voltage on the select word line to the first supply voltage.

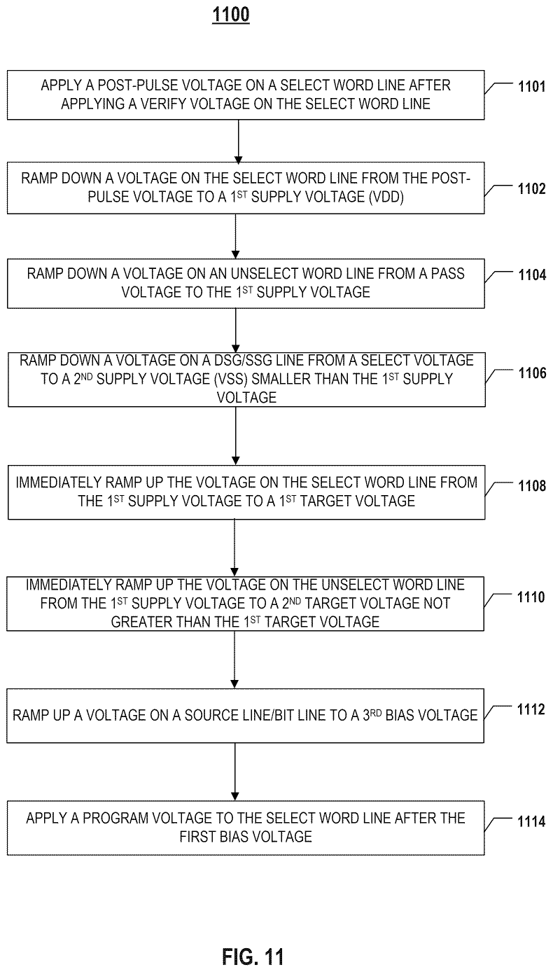

FIG. 11 illustrates a flowchart of a method 1100 for programming a memory device, according to some aspects of the present disclosure. The memory device may be any suitable memory device disclosed herein, such as memory device 100. Method 1100 may be implemented by peripheral circuit 102, such as row decoder/word line driver 308, page buffer/sense amplifier 304, and control logic 312. It is understood that the operations shown in method 1100 may not be exhaustive and that other operations can be performed as well before, after, or between any of the illustrated operations. Further, some of the operations may be performed simultaneously, or in a different order than shown in FIG. 11.

Referring to FIG. 11, method 1100 starts at operation 1101, in which, in a first loop of a program operation, a post-pulse voltage is applied on a select word line of the word lines after applying a verify voltage on the select word line. Method 1100 proceeds to operation 1102, as illustrated in FIG. 11, in which a voltage on the select word line is ramped down from the post-pulse voltage to a first supply voltage (Vdd). For example, as shown in FIGS. 7 and 8, in the verify period of verify cycle 406 in a first loop, the verify voltage (Vvfy) is applied to the select word line (sel WLn), and at time t1, the post-pulse voltage (Vpost) is applied to the select word line. The voltage on the select word line is then ramped down from the post-pulse voltage at the first time t1 to the first supply voltage (Vdd) at the second time t2.

Method 1100 proceeds to operation 1104, as illustrated in FIG. 11, in which a voltage on an unselect word line is ramped down from a pass voltage to the first supply voltage. In some implementations, the voltages on the select word line and the unselect word line are ramped down from a same first time and ramped up from a same second time. For example, as shown in FIGS. 7 and 8, the voltage on each unselect word line is ramped down from the pass voltage (Vpass) at the first time t1 to the first supply voltage at the second time t2.

Method 1100 proceeds to operation 1106, as illustrated in FIG. 11, in which a voltage on the DSG line/SSG line is ramped down from a select voltage to a second supply voltage (Vss) smaller than the first supply voltage. In some implementations, the voltages on the select word line and the DSG line/SSG line are ramped down from a same first time until a same second time. For example, as shown in FIG. 7, the voltage on the DSG line (DSGL) is ramped down from the select voltage at the first time t1 to the second supply voltage (Vss) at the second time t2. For example, as shown in FIG. 8, the voltage on the SSG line (SSGL) is ramped down from the select voltage at the first time t1 to the second supply voltage (Vss) at the second time t2.

Method 1100 proceeds to operation 1108, as illustrated in FIG. 11, in which the voltage on the select word line is immediately ramped up from the first supply voltage to a first bias voltage. In some implementations, to immediately ramp up the voltage on the select word line, the voltage on the select word line is ramped up as soon as the voltage on the select word line reaches the first supply voltage. For example, as shown in FIGS. 7 and 8, the voltage on the select word line is immediately ramped up from the first supply voltage at the second time t2 (as soon as the voltage on the select word line reaches the first supply) voltage to the first bias voltage (V1).

Method 1100 proceeds to operation 1110, as illustrated in FIG. 11, in which the voltage on the unselect word line is immediately ramped up from the first supply voltage to a second bias voltage not greater than the first bias voltage. In some implementations, the unselect word line includes a first unselect word line, a second unselect word line, and a third unselect word line. In some implementations, the first unselect word line is closer to the select word line than the second unselect word line, and the second unselect word line is closer to the select word line than the third unselect word line. In some implementations, the second bias voltage on the first unselect word line is the same as the first bias voltage on the select word line, the second bias voltage on the second unselect word line is smaller than the first bias voltage, and the third bias voltage on the third unselect word line is smaller than the second bias voltage on the second unselect word line. For example, as shown in FIGS. 7 and 8, the voltage on each unselect word line is immediately ramped up from the first supply voltage at the second time t2 (as soon as the voltage on the select word line reaches the first supply) voltage to the respective bias voltage (V1, V2, or V3). The first bias voltage (V1) on each unselect word line in a first group (WLn-4-WLn-1 in FIG. 7, or WLn+1-WLn+4) is the same as that on the unselect word line; the second bias voltage (V2) on each unselect word line in a second group (WLb+1-WLn-5 and WLn+1-WLx in FIG. 7, and WLa+1-WLn-1 and WLn+5-WLx in FIG. 8) is smaller than the first bias voltage; the third bias voltage (V3) on each unselect word line in a third group (WLa+1-WLb in FIG. 7, and WLx+1-WLy in FIG. 8) is smaller than the second bias voltage. The first group of unselect word lines is closer to the select word line than the second group of unselect word lines, and the second group of unselect word lines is closer to the selected word line than the third group of unselect word lines.

Method 1100 proceeds to operation 1112, as illustrated in FIG. 11, in which a voltage on a source line/bit line is ramped up to a fourth bias voltage. For example, as shown in FIG. 7, the voltage on the source line (SL) is ramped up at the first time t1 to the fourth bias voltage (V4) at the second time t2. For example, as shown in FIG. 7, the voltage on the bit line (BL) is ramped up at the first time t1 to the fourth bias voltage (V4) at the second time t2.

Method 1100 proceeds to operation 1114, as illustrated in FIG. 11, in which a program voltage is applied to the select word line after the first bias voltage in a second loop of the program operation immediately after the first loop. For example, as shown in FIGS. 7 and 8, in program cycle 404 in the second loop, a program voltage (Vpgm) is applied to the select word line after the first bias voltage (V1).

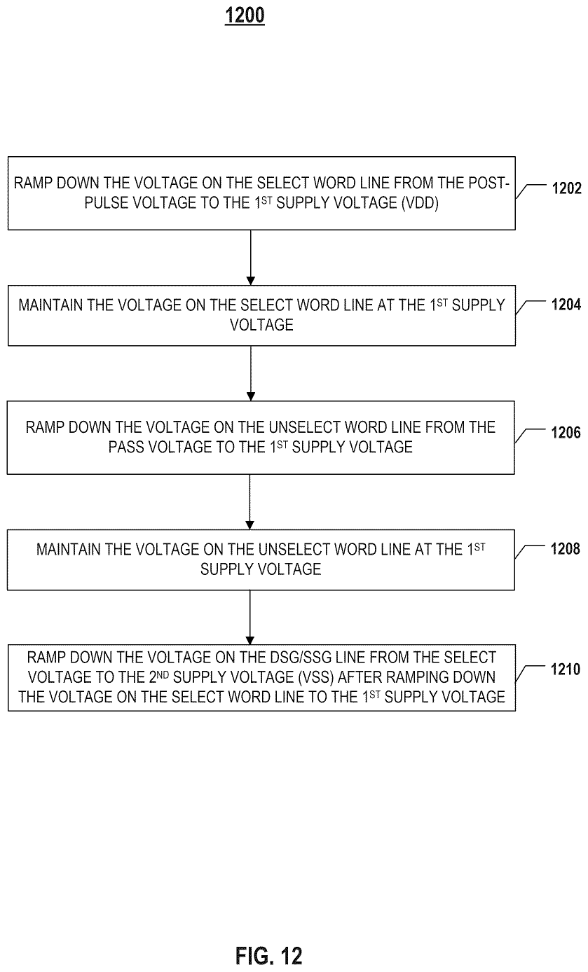

FIG. 12 illustrates a flowchart of another method 1200 for programming a memory device, according to some aspects of the present disclosure. The memory device may be any suitable memory device disclosed herein, such as memory device 100. Method 1200 may be implemented by peripheral circuit 102, such as row decoder/word line driver 308, page buffer/sense amplifier 304, and control logic 312. It is understood that the operations shown in method 1200 may not be exhaustive and that other operations can be performed as well before, after, or between any of the illustrated operations. Further, some of the operations may be performed simultaneously, or in a different order than shown in FIG. 12.

Referring to FIG. 12, method 1200 starts at operation 1202, in which, in a third loop of the program operation, the voltage on the select word line is ramped down from the post-pulse voltage to the first supply voltage. Method 1200 proceeds to operation 1204, as illustrated in FIG. 12, in which the voltage on the select word line is maintained at the first supply voltage. For example, as shown in FIG. 10, in verify cycle 406 of the third loop, the voltage on the select word line is ramped down from the post-pulse voltage (Vpost) to the first supply voltage (Vdd), and then maintained at the first supply voltage.

Method 1200 proceeds to operation 1206, as illustrated in FIG. 12, in which the voltage on the unselect word line is ramped down from the pass voltage to the first supply voltage Method 1200 proceeds to operation 1208, as illustrated in FIG. 12, in which the voltage on the unselect word line is maintained at the first supply voltage. For example, as shown in FIG. 10, in verify cycle 406 of the third loop, the voltage on each unselect word line is ramped down from the pass voltage (Vpass) to the first supply voltage (Vdd), and then maintained at the first supply voltage.

Method 1200 proceeds to operation 1210, as illustrated in FIG. 12, in which the voltage on the DSG line/SSG line is ramped down from the select voltage to the second supply voltage after ramping down the voltage on the select word line to the first supply voltage. For example, as shown in FIG. 10, the voltage on the DSG line (DSGL)/SSG line (SSGL) is ramped down from the select voltage to the second supply voltage (Vss) after ramping down the voltage on the select word line to the first supply voltage.

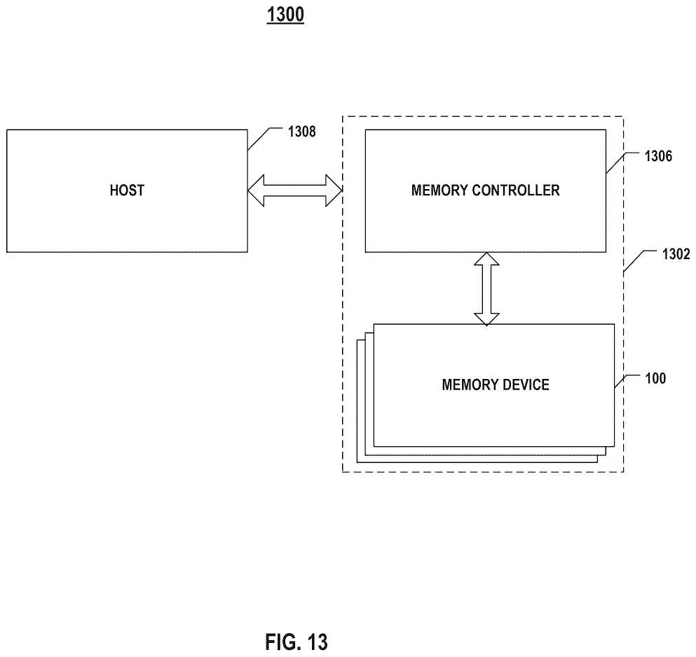

FIG. 13 illustrates a block diagram of a system 1300 having a memory device, according to some aspects of the present disclosure. System 1300 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 13, system 1300 can include a host 1308 and a memory system 1302 having one or more memory devices 100 (shown in FIG. 1) and a memory controller 1306. Host 1308 can be a processor of an electronic device, such as a central processing unit (CPU), or a system-on-chip (SoC), such as an application processor (AP). Host 1308 can be configured to send or receive data to or from memory devices 100.

Memory device 100 can be any memory device disclosed in the present disclosure. Memory controller 1306 is coupled to memory device 100 and host 1308 and is configured to control memory device 100, according to some implementations. Memory controller 1306 can manage the data stored in memory device 100 and communicate with host 1308. In some implementations, memory controller 1306 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1306 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1306 can be configured to control operations of memory device 100, such as read, erase, and program operations. Memory controller 1306 can also be configured to manage various functions with respect to the data stored or to be stored in memory device 100 including, but not limited to bad-block management, garbage collection, logical-to-physical address conversion, wear leveling, etc. In some implementations, memory controller 1306 is further configured to process error correction codes (ECCs) with respect to the data read from or written to memory device 100. Any other suitable functions may be performed by memory controller 1306 as well, for example, formatting memory device 100. Memory controller 1306 can communicate with an external device (e.g., host 1308) according to a particular communication protocol. For example, memory controller 1306 may communicate with the external device through at least one of various interface protocols, such as a USB protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

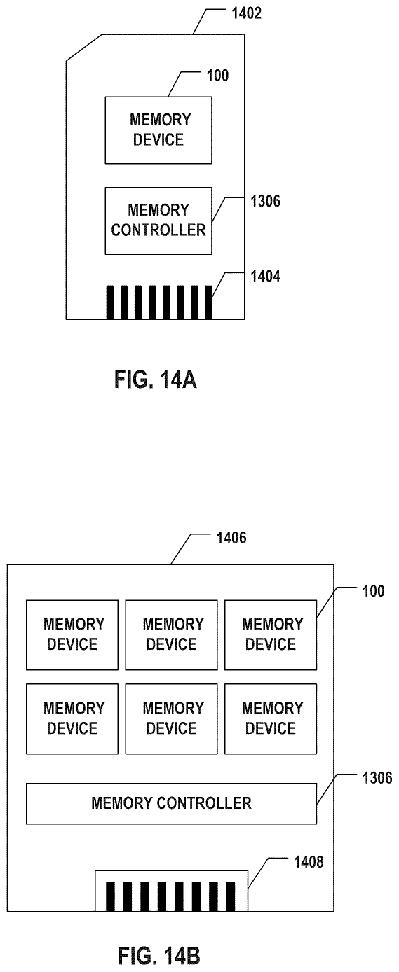

Memory controller 1306 and one or more memory devices 100 can be integrated into various types of storage devices, for example, being included in the same package, such as a universal Flash storage (UFS) package or an eMMC package. That is, memory system 1302 can be implemented and packaged into different types of end electronic products. In one example as shown in FIG. 14A, memory controller 1306 and a single memory device 100 may be integrated into a memory card 1402. Memory card 1402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1402 can further include a memory card connector 1404 coupling memory card 1402 with a host (e.g., host 1308 in FIG. 13). In another example as shown in FIG. 14B, memory controller 1306 and multiple memory devices 100 may be integrated into an SSD 1406. SSD 1406 can further include an SSD connector 1408 coupling SSD 1406 with a host (e.g., host 1308 in FIG. 13). In some implementations, the storage capacity and/or the operation speed of SSD 1406 is greater than those of memory card 1402.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents.

Although specific configurations and arrangements are discussed, it should be understood that this is done for illustrative purposes only. As such, other configurations and arrangements can be used without departing from the scope of the present disclosure. Also, the subject matter as described in the present disclosure can also be used in a variety of other applications. Functional and structural features as described in the present disclosures can be combined, adjusted, modified, and rearranged with one another and in ways that are consistent with the scope of the present disclosure.

What is claimed is:

1. A memory device, comprising:
an array of memory cells;
word lines respectively coupled to rows of the array of memory cells; and
a peripheral circuit coupled to the array of memory cells through the word lines and configured to, in a first loop of a program operation:
apply a post-pulse voltage on a select word line of the word lines after applying a verify voltage on the select word line;
ramp down a voltage on the select word line from the post-pulse voltage to a first supply voltage (Vdd); and
immediately ramp up the voltage on the select word line from the first supply voltage to a first bias voltage.

2. The memory device of claim 1, wherein to immediately ramp up the voltage on the select word line, the peripheral circuit is configured to ramp up the voltage on the select word line as soon as the voltage on the select word line reaches the first supply voltage.

3. The memory device of claim 1, wherein the peripheral circuit is further configured to, in a second loop of the program operation immediately after the first loop, apply a program voltage to the select word line after the first bias voltage.

4. The memory device of claim 1, wherein the peripheral circuit is further configured to, in the first loop of the program operation:
ramp down a voltage on an unselect word line of the word lines from a pass voltage to the first supply voltage; and
immediately ramp up the voltage on the unselect word line from the first supply voltage to a second bias voltage not greater than the first bias voltage.

5. The memory device of claim 4, wherein the voltages on the select word line and the unselect word line are ramped down from a same first time and ramped up from a same second time.

6. The memory device of claim 4, wherein
the unselect word line comprises a first unselect word line, a second unselect word line, and a third unselect word line, the first unselect word line being closer to the select word line than the second unselect word line, the second unselect word line being closer to the select word line than the third unselect word line;
the second bias voltage on the first unselect word line is the same as the first bias voltage on the select word line;
the second bias voltage on the second unselect word line is smaller than the first bias voltage; and
a third bias voltage on the third unselect word line is smaller than the second bias voltage on the second unselect word line.

7. The memory device of claim 1, further comprising:
a source line coupled to the array of memory cells;
drain select gate (DSG) transistors respectively coupled to columns of the array of memory cells; and
a DSG line coupled to the DSG transistors,
wherein the peripheral circuit is coupled to the array of memory cells through the source line and the DSG line and is configured to, in the first loop of the program operation:
ramp down a voltage on the DSG line from a select voltage to a second supply voltage (Vss) smaller than the first supply voltage; and
ramp up a voltage on the source line to a third bias voltage.

8. The memory device of claim 7, wherein the voltages on the select word line and the DSG line are ramped down from a same first time until a same second time.

9. The memory device of claim 1, further comprising:
a bit line coupled to the array of memory cells;
source select gate (SSG) transistors respectively coupled to columns of the array of memory cells; and
an SSG line coupled to the SSG transistors,
wherein the peripheral circuit is coupled to the array of memory cells through the bit line and the SSG line and is configured to, in the first loop of the program operation:
ramp down a voltage on the SSG line from a select voltage to a second supply voltage (Vss) smaller than the first supply voltage; and
ramp up a voltage on the bit line to a third bias voltage.

10. The memory device of claim 9, wherein the voltages on the select word line and the SSG line are ramped down from a same first time until a same second time.

11. The memory device of claim 1, wherein the peripheral circuit is further configured to, in a third loop of the program operation;
ramp down the voltage on the select word line from the post-pulse voltage to the first supply voltage; and
maintain the voltage on the select word line at the first supply voltage.

12. A method for operating a memory device comprising an array of memory cells and word lines respectively coupled to rows of the memory cells, the method comprising, in a first loop of a program operation:
applying a post-pulse voltage on a select word line of the word lines after applying a verify voltage on the select word line;
ramping down a voltage on the select word line from the post-pulse voltage to a first supply voltage (Vdd); and
immediately ramping up the voltage on the select word line from the first supply voltage to a first bias voltage.

13. The method of claim 12, wherein immediately ramping up the voltage on the select word line comprises ramping up the voltage on the select word line as soon as the voltage on the select word line reaches the first supply voltage.

14. The method of claim 12, further comprising, in a second loop of the program operation immediately after the first loop, applying a program voltage to the select word line after the first bias voltage.

15. The method of claim 12, further comprising, in the first loop of the program operation:
ramping down a voltage on an unselect word line of the word lines from a pass voltage to the first supply voltage; and
immediately ramping up the voltage on the unselect word line from the first supply voltage to a second bias voltage not greater than the first bias voltage.

16. The method of claim 15, wherein the voltages on the select word line and the unselect word line are ramped down from a same first time and ramped up from a same second time.

17. The method of claim 12, wherein
the memory device further comprises a source line coupled to the array of memory cells, drain select gate (DSG) transistors respectively coupled to columns of the memory cells, and a DSG line coupled to the DSG transistors; and
the method further comprises, in the first loop of the program operation:
ramping down a voltage on the DSG line from a select voltage to a second supply voltage (Vss) smaller than the first supply voltage; and
ramping up a voltage on the source line to a fourth bias voltage.

18. The method of claim 12, wherein
the memory device further comprises a bit line coupled to the array of memory cells, source select gate (SSG) transistors respectively coupled to columns of array of the memory cells, and an SSG line coupled to the SSG transistors; and
the method further comprises, in the first loop of the program operation:
ramping down a voltage on the SSG line from a select voltage to a second supply voltage (Vss) smaller than the first supply voltage; and
ramping up a voltage on the bit line to a fourth bias voltage.

19. The method of claim 12, further comprising, in a third loop of the program operation;
ramping down the voltage on the select word line from the post-pulse voltage to the first supply voltage; and
maintaining the voltage on the select word line at the first supply voltage.

20. A system, comprising:
a memory device configured to store data and comprising:
an array of memory cells;
word lines respectively coupled to rows of the array of memory cells; and
a peripheral circuit coupled to the array of memory cells through the word lines and configured to, in a first loop of a program operation:
apply a post-pulse voltage on a select word line of the word lines after applying a verify voltage on the select word line;
ramp down a voltage on the select word line from the post-pulse voltage to a first supply voltage (Vdd); and
immediately ramp up the voltage on the select word line from the first supply voltage to a first bias voltage; and
a memory controller coupled to the memory device and configured to control the memory device.
